(19) United States
(12) Patent Application Publication
(10) Pub. No.: US 2025/0084352 A1
(43) Pub. Date: Mar. 13, 2025

(54) THINNER COMPOSITION AND METHOD FOR SUBSTRATE PROCESSING

(71) Applicant: Advanced Echem Materials Company Limited, Taoyuan (TW)

(72) Inventors: Chen-Jing Guo, Taoyuan (TW); Shan Lu, Taoyuan (TW); Yu-Lun Li, Taoyuan (TW)

(73) Assignee: Advanced Echem Materials Company Limited, Taoyuan (TW)

(21) Appl. No.: 18/826,109

(22) Filed: Sep. 5, 2024

(30) Foreign Application Priority Data
Sep. 13, 2023 (TW) 112134774

(51) Int. Cl. C11D 7/32; C11D 7/28; C11D 7/50; H01L 21/02

(52) U.S. Cl. CPC C11D 7/3254; C11D 7/28; C11D 7/5022; H01L 21/02057

(57) ABSTRACT

A thinner composition and a method for substrate processing are provided. The thinner composition includes a solvent (A) and a fluorine-containing additive (B). The fluorine-containing additive (B) includes a compound represented by following Formula (B-1), a polymer represented by following Formula (B-2), a polymer represented by following Formula (B-3), or a combination thereof.

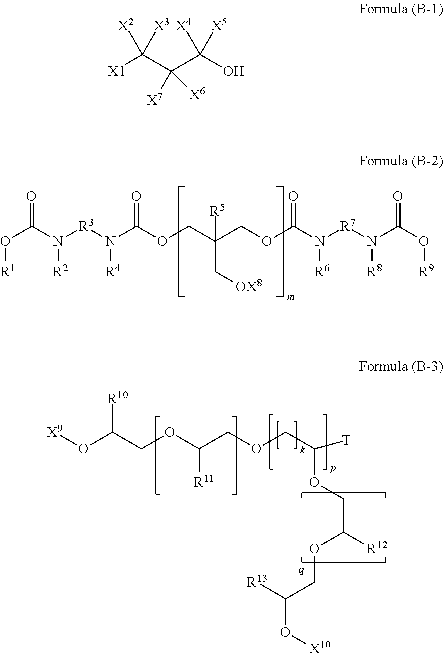

In Formula (B-1), Formula (B-2), and Formula (B-3), the definition of X¹ to X¹⁰, R¹ to R¹³, m, T, j, k, p, and q are the same as defined in the specification.

### CROSS-REFERENCE TO RELATED APPLICATION

This application claims the priority benefit of Taiwan application serial no. 112134774, filed on Sep. 13, 2023. The entirety of the above-mentioned patent application is hereby incorporated by reference herein and made a part of this specification.

### BACKGROUND

### Technical Field

The disclosure relates to a thinner composition, and particularly relates to a thinner composition and a method for substrate processing.

### Description of Related Art

With the vigorous development of semiconductor devices, display devices, or optical elements, in order to expand the application aspects thereof, the demand for performance and quality has gradually increased. For example, during the manufacturing process of semiconductor devices, generally, a photoresist composition is coated on the substrate to form a photoresist layer. However, the photoresist composition may form accumulations of different sizes on the surface of the substrate, leading to, for example, focus phenomena during the subsequent manufacturing process, and thus the performance of the device produced is affected.

### SUMMARY

The disclosure provides a thinner composition and a method for substrate processing that can effectively remove protrusions on the edge of the substrate.

The disclosure provides a thinner composition. The thinner composition includes a solvent (A) and a fluorine-containing additive (B). The fluorine-containing additive (B) includes a compound represented by the following Formula (B-1), a polymer represented by the following Formula (B-2), a polymer represented by the following Formula (B-3), or a combination thereof:

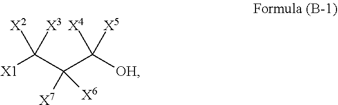

in Formula (B-1), X¹ to X⁷ each represent hydrogen, fluorine, or a fluorine-containing alkyl group having 1 to 2 carbon atoms, and at least one of X¹ to X⁷ is fluorine or a fluorine-containing alkyl group having 1 to 2 carbon atoms;

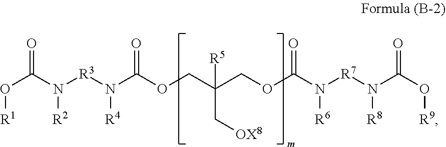

in Formula (B-2), R¹ and R⁹ each represent C_{y}H_{2y-3}O_{z}, in which y represents an integer of 4 to 25, and z represents an integer of 1 to 7,
R², R⁴, R⁵, R⁶, and R⁸ each represent hydrogen, an alkyl group having 1 to 5 carbon atoms, or an alkoxy group having 1 to 5 carbon atoms,
R³ and R⁷ each represent CₙH₂ₙ₋₂, in which n represents an integer of 4 to 25,
X⁸ represents a fluorine-containing alkyl group having 1 to 3 carbon atoms,
m represents an integer of 2 to 39,
when m is an integer greater than or equal to 3, multiple R⁵s are the same as or different from each other, and multiple X⁸s are the same as or different from each other;

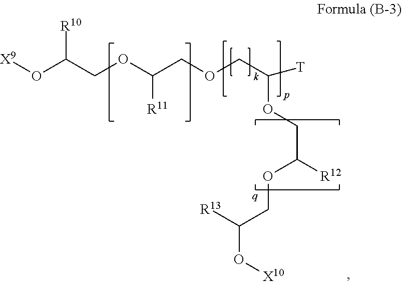

in Formula (B-3), X⁹ and X¹⁰ each represent CᵣF₂ᵣ₋₁, in which r represents an integer of 2 to 15, R¹⁰ to R¹³ each represent hydrogen, an alkyl group having 1 to 3 carbon atoms, an alkoxy group having 1 to 3 carbon atoms, or a hydroxyl group,
T represents hydrogen, an alkyl group having 1 to 3 carbon atoms, an alkoxy group having 1 to 3 carbon atoms, a hydroxyl group, a carboxyl group, *—COOCH₃, *—COOC₂H₅, an aldehyde group, an amine group, *—OSO₃H, *—OSO₃NH₄, *—OSO₃Na, *—OSO₃K, in which * represents a bonding position,
j and q each represent an integer of 2 to 30,
k represents an integer of 0 to 20,
p represents an integer of 1 to 9,
when j, k, p, and q are each an integer greater than or equal to 2, multiple R¹¹s are the same as or different from each other, multiple R¹²s are the same as or different from each other, multiple R¹³s are the same as or different from each other, and multiple X¹⁰s are the same as or different from each other.

In an embodiment of the disclosure, the solvent (A) includes propylene glycol monomethyl ether, propylene glycol monomethyl ether acetate, n-butyl acetate, N-methylpyrrolidone, isobutanol, 4-methyl-2-pentanol, γ-butyrolactone, cyclohexanone, cyclohexanol, dimethyl sulfoxide, ethanol, methanol, butanol, or a combination thereof.

In an embodiment of the disclosure, the solvent (A) is a mixed solvent. The mixed solvent is formed by mixing at least two different organic solvents.

In an embodiment of the disclosure, the boiling point of the mixed solvent is 70° C. to 170° C., and the turbidity is less than or equal to 0.02 NTU.

In an embodiment of the disclosure, the solvent (A) includes propylene glycol monomethyl ether, and further includes at least one of propylene glycol monomethyl ether acetate, n-butyl acetate, N-methylpyrrolidone, isobutanol, 4-methyl-2-pentanol, γ-butyrolactone, cyclohexanone, cyclohexanol, dimethyl sulfoxide, ethanol, methanol, and butanol.

In an embodiment of the disclosure, the solvent (A) is a mixed solvent formed by mixing propylene glycol monomethyl ether and n-butyl acetate. The mixing ratio of propylene glycol monomethyl ether and n-butyl acetate is 5:95 to 45:55.

In an embodiment of the disclosure, the solvent (A) is a mixed solvent formed by mixing propylene glycol monomethyl ether and propylene glycol monomethyl ether acetate. The mixing ratio of propylene glycol monomethyl ether and propylene glycol monomethyl ether acetate is 50:50 to 90:10.

In an embodiment of the disclosure, based on 100 parts by weight of the thinner composition, the amount of fluorine-containing additive (B) is 0.001 parts by weight to 3 parts by weight.

A method for substrate processing of the disclosure includes applying the thinner composition to a surface of the substrate.

In an embodiment of the disclosure, the thinner composition is applied to the edge of the surface of the substrate.

In an embodiment of the disclosure, a photoresist composition has been coated on the surface of the substrate. The thinner composition removes protrusions on the edge of a surface of the photoresist composition.

Based on the above, the thinner composition of the disclosure includes a fluorine-containing additive (B) having a specific structure. In this way, the thinner composition can effectively remove the protrusions on the edge of the substrate when used in the method for substrate processing.

In order to make the above-mentioned features and advantages of the disclosure more obvious and understandable, examples are given below for detailed description.

### DESCRIPTION OF THE EMBODIMENTS

### Thinner Composition

The disclosure provides a thinner composition, which includes a solvent (A) and a fluorine-containing additive (B). In addition, the thinner composition of the disclosure may include other suitable additives as necessary. The various constituents mentioned above will be described in detail as follows.

### Solvent (A)

There are no particular limitations on the solvent (A), and suitable solvents may be chosen according to requirements. For example, the solvent (A) may include propylene glycol monomethyl ether, propylene glycol monomethyl ether acetate, n-butyl acetate, N-methylpyrrolidone, isobutanol, 4-methyl-2-pentanol, γ-butyrolactone, cyclohexanone, cyclohexanol, dimethyl sulfoxide, ethanol, methanol, butanol, a combination thereof, or other suitable solvents.

In this embodiment, the solvent (A) may preferably be a mixed solvent. The mixed solvent may be formed by mixing at least two different organic solvents. The boiling point of the mixed solvent may be 70° C. to 170° C., preferably 80° C. to 150° C. The turbidity of the mixed solvent may be less than or equal to 0.02 NTU, preferably 0.001 NTU to 0.01 NTU. The solvent (A) may preferably be mixed with propylene glycol monomethyl ether and other solvents to form the mixed solvent. For example, the solvent (A) may include propylene glycol monomethyl ether, and may further include at least one of propylene glycol monomethyl ether acetate, n-butyl acetate, N-methylpyrrolidone, isobutanol, 4-methyl-2-pentanol, γ-butyrolactone, cyclohexanone, cyclohexanol, dimethyl sulfoxide, ethanol, methanol, and butanol. In this embodiment, the solvent (A) is preferably a mixed solvent formed by mixing propylene glycol monomethyl ether and n-butyl acetate or a mixed solvent formed by mixing propylene glycol monomethyl ether and propylene glycol monomethyl ether acetate.

In the mixed solvent formed by mixing propylene glycol monomethyl ether and n-butyl acetate, the mixing ratio of propylene glycol monomethyl ether and n-butyl acetate may be 5:95 to 45:55, preferably 10:90 to 40:60. For example, when the mixing ratio of propylene glycol monomethyl ether and n-butyl acetate is 20:80, the turbidity is approximately 0.003 NTU. When the mixing ratio of propylene glycol monomethyl ether and n-butyl acetate is 40:60, the turbidity is approximately 0.003NTU.

In the mixed solvent formed by mixing propylene glycol monomethyl ether and propylene glycol monomethyl ether acetate, the mixing ratio of propylene glycol monomethyl ether and propylene glycol monomethyl ether acetate may be 50:50 to 90:10, preferably 60:40 to 80:20. For example, when the mixing ratio of propylene glycol monomethyl ether and propylene glycol monomethyl ether acetate is 70:30, the turbidity is approximately 0.003 NTU.

When the thinner composition includes the solvent (A), the thinner composition can have an appropriate viscosity and thus can be applied to the substrate surface effectively, so as to effectively remove protrusions on the edge of the substrate.

### Fluorine-Containing Additive (B)

The fluorine-containing additive (B) includes a compound represented by the following Formula (B-1), a polymer represented by the following Formula (B-2), a polymer represented by the following Formula (B-3), or a combination thereof. The fluorine-containing additive (B) may further include other suitable fluorine-containing additives.

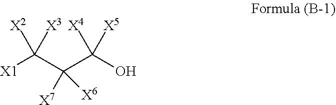

In Formula (B-1), X¹ to X⁷ each represent hydrogen, fluorine, or a fluorine-containing alkyl group having 1 to 2 carbon atoms, preferably fluorine, difluoromethyl, or fluoromethyl; at least one of X¹ to X⁷ is fluorine or a fluorine-containing alkyl group having 1 to 2 carbon atoms, and preferably at least five of X¹ to X⁷ are fluorine, difluoromethyl, or fluoromethyl.

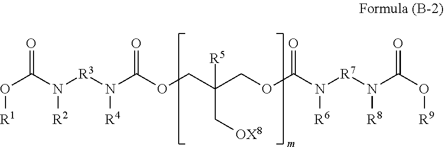

In Formula (B-2), R¹ and R⁹ each represent C_{y}H_{2y-3}O_{z}, in which y represents an integer of 4 to 25, preferably an integer of 5 to 15; z represents an integer of 1 to 7, preferably an integer of 1 to 4;
R², R⁴, R⁵, R⁶ and R⁸ each represent hydrogen, an alkyl group having 1 to 5 carbon atoms, or an alkoxy group having 1 to 5 carbon atoms, preferably hydrogen, methyl, ethyl, methoxy, or ethoxy; R³ and R⁷ each represent CₙH₂ₙ₋₂, in which n represents an integer of 4 to 25, preferably an integer of 5 to 19;
X⁸ represents a fluorine-containing alkyl group having 1 to 3 carbon atoms, preferably trifluoromethyl, difluoroethyl, trifluoroethyl, tetrafluoroethyl, pentafluoroethyl, or pentafluoropropyl;
m represents an integer of 2 to 39, preferably an integer of 3 to 29;
when m is an integer greater than or equal to 3, multiple R⁵s are the same as or different from each other, and multiple X⁸s are the same as or different from each other.

In this embodiment, R¹ and R⁹ are preferably oxyalkylene groups (such as 1,3 butadiene ethoxy, 1,4 pentadiene methoxy), ester alkenyl groups (such as ethyl acrylate groups, methyl crotonate groups, propyl vinyl ester groups), or cycloalkoxy groups (such as cyclohexanone methoxy groups, cyclopentanone ethoxy groups). R³ and R⁷ each include a ring or an unsaturated bond (such as a cycloalkyl group, an alkenyl group, a cycloalkylene group, or an alkenylene group), preferably a cycloalkyl group or a cycloalkylene group. R³ and R⁷ are preferably an alkenylene group (such as

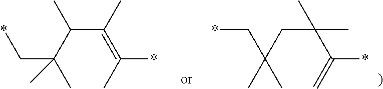 [SMILES: *CC(C)(C)C(C)/C(C)=C(/*)C ; *CC(C)(C)CC(C)(C)C(*)=C]

or a cycloalkylene group (such as

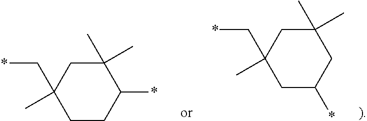

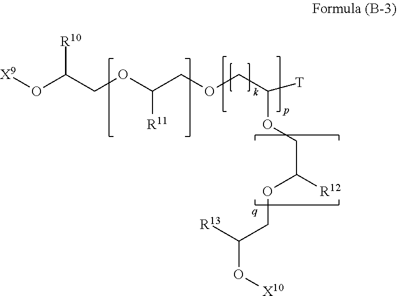

In Formula (B-3), X⁹ and X¹⁰ each represent CᵣF₂ᵣ₋₁, in which r represents an integer of 2 to 15, preferably an integer of 3 to 12;
R¹⁰ to R¹³ each represent hydrogen, an alkyl group having 1 to 3 carbon atoms, an alkoxy group having 1 to 3 carbon atoms, or a hydroxyl group, preferably hydrogen, a methyl group, an ethyl group, methoxy, or ethoxy;
T represents hydrogen, an alkyl group having 1 to 3 carbon atoms, an alkoxy group having 1 to 3 carbon atoms, a hydroxyl group, a carboxyl group, *—COOCH₃, *—COOC₂H₅, an aldehyde group, an amine group, *—OSO₃H, *—OSO₃NH₄, *—OSO₃Na, *—OSO₃K, in which * represents a bonding position, preferably hydrogen, a methyl group, an ethyl group, methoxy, ethoxy, a hydroxyl group, or a carboxyl group;
j represents an integer of 2 to 30, preferably an integer of 2 to 20;
q represents an integer of 2 to 30, preferably an integer of 2 to 20;
k represents an integer of 0 to 20, preferably an integer of 2 to 13;
p represents an integer of 1 to 9, preferably an integer of 1 to 5;
when j, k, p, and q are each an integer greater than or equal to 2, multiple R¹¹s are the same as or different from each other, multiple R¹²s are the same as or different from each other, multiple R¹³s are the same as or different from each other, and multiple X¹¹s are the same as or different from each other.

In this embodiment, X⁹ and X¹⁰ each include a ring or an unsaturated bond (such as a cycloalkyl group, an alkenyl group, a cycloalkylene group, or an alkenylene group), preferably an alkenyl group or an alkenylene group. X⁹ and X¹⁰ are preferably fluorine-containing cycloalkyl groups (such as 1-(1,1,1-trifluoromethyl)-1,2,2,3,3,4,5,5,6,6-decafluorocyclohexane-4,4-difluoromethyl, 1,2,2,3,4,5,5-heptafluorocyclopentane-3,4-bistrifluoromethyl-1-(1,1,2,2,3,3-hexafluoropropyl, 1,2,2,3,4,4,5,6,6-nonafluorocyclohexane-3,5-bistrifluoromethyl-1-(1,1,2,2,3,3-hexafluoropropyl), fluorine-containing alkenyl groups (such as 4-perfluoroisopropyl-2,5-bistrifluoromethyl-1,1,1,2,5,6,6,6-octafluoro-3-hexenyl, 3-perfluoropropyl-5-trifluoromethyl-1,1,1,4,4,5,6,6,6-nonafluoro-2-hexenyl, 3-perfluoroisopropyl-4-trifluoromethyl-1,1,1,4,5,5,5,-heptafluoro-2-pentenyl, 3-perfluoroethyl-1,1,1,4,4,5,5,6,6,6-decafluoro-2-hexenyl), or fluorine-containing alkenylene groups (such as 3,4-perfluoroethyl-1,1,1,2,2,5,6,6,7,7,7-undecafluoro-3-heptenyl, 3,4-perfluoroethyl-1,1,1,2,2,5,6,6,6-nonafluoro-3-hexenyl, 3-perfluoroethyl-4-difluoromethyl-1,1,2,3,4,5,5,6,6,6-decafluoro-1-hexenyl, 3-perfluoroethyl-1,1,1,2,2,4,5,5,6,6-decafluoro-3-hexenyl). The molecular weight of the compound represented by Formula (B-3) is 1,000 to 10,000, preferably 2,000 to 5,000.

Based on 100 parts by weight of the thinner composition, the amount of the fluorine-containing additive (B) is 0.001 parts by weight to 3 parts by weight, preferably 0.01 parts by weight to 1.0 parts by weight.

When the thinner composition includes the fluorine-containing additive (B) having a specific structure, the thinner composition can effectively remove the protrusions on the edge of the substrate when used in the method for substrate processing. For example, when a photoresist composition is coated on the substrate surface and protrusions exist on the edge of the photoresist composition surface, the fluorine-containing additive (B) having the specific structure can reduce the high intermolecular force in the photoresist composition, thereby reducing the phenomenon of protrusions occurring on the edge of the surface of the photoresist formed by the photoresist composition, which can effectively remove the protrusions from the edge of the substrate.

### Preparation Method of Thinner Composition

The preparation method of the thinner composition is not particularly limited. For example, place the solvent (A) and the fluorine-containing additive (B) in a stirrer and stir until evenly mixed into a solution. If necessary, other suitable additives may also be added. After mixing evenly, a liquid thinner composition may be obtained.

### Method for Substrate Processing

An exemplary embodiment of the disclosure provides a method for substrate processing including applying the thinner composition to a substrate surface.

For example, the method for substrate processing may include the following. A photoresist composition is coated on the substrate surface, and protrusions may be formed on the edge of the substrate surface. The thinner composition is applied to the substrate surface, particularly to the edge of the substrate surface. The protrusions on the edge of the surface are removed.

In this embodiment, the photoresist composition may be coated on the substrate surface first, and then the thinner composition is applied to the surface of the photoresist composition. For example, when the photoresist composition is coated on the substrate surface, the photoresist composition is likely to form protrusions on the edge of the substrate surface, that is, to form protrusions on the edge of the photoresist surface. Therefore, the thinner composition is preferably applied to the edge of the substrate surface or the edge of the photoresist surface.

The substrate may be a wafer, a glass substrate, a plastic substrate material (such as a polyether styrene (PES) board, a polycarbonate (PC) board, or a polyimide (PI) film) or other light-transmissive substrates, and the type thereof is not particularly limited.

The photoresist composition may be a positive photoresist composition or a negative photoresist composition. The positive photoresist composition may include a resin, a photosensitizer, a monomer, a solvent, or other suitable additives. The negative photoresist composition may include a resin, a photoinitiator, a monomer, a solvent, or other suitable additives.

The method of coating the photoresist composition onto the substrate surface is not particularly limited, but spray coating, roller coating, spin coating, or similar methods may be used, and in general, spin coating is widely used.

The method of applying the thinner composition to the substrate surface or the photoresist composition surface is not particularly limited, and in general, spray coating is widely used.

Hereinafter, the disclosure will be described in detail with reference to examples. The following examples are provided to describe the disclosure, and the scope of the disclosure includes the scope described in the following claims and the substitutions and modifications thereof, and not limited to the scope of the examples.

### Embodiments of Thinner Composition

Embodiment 1 to Embodiment 11 and Comparative Example 1 to Comparative Example 3 of the thinner composition are described below.

### Embodiment 1

0.6 parts by weight of a fluorine-containing additive (B-1) is added to 99.4 parts by weight of a solvent (A-1) (a mixed solvent being a mixer of 80 parts by weight of n-butyl acetate (NBAC) and 20 parts by weight of propylene glycol monomethyl ether (PGME)), and after stirring evenly with a stirrer, the thinner composition of Embodiment 1 may be obtained.

### Embodiment 2 to Embodiment 11 and Comparative Example 1 to Comparative Example 3

The thinner compositions of Embodiment 2 to Embodiment 11 and Comparative Example 1 to Comparative Example 3 are prepared by the same operations as in Embodiment 1, and the difference is that, the types and usage amounts of ingredients of the thinner composition are changed (as shown in Table 1). The thinner compositions obtained is evaluated according to the following evaluation methods, and the results are shown in Table 2.

TABLE 1

| | Reference | |
|---|---|---|
| | Numeral | Constituent/Compound |
| Solvent (A) | A-1 | A mixed solvent formed by mixing 80 parts by weight of n-butyl |
| | | acetate (NBAC) and 20 parts by weight of propylene glycol |
| | | monomethyl ether (PGME) |
| | A-2 | A mixed solvent formed by mixing 60 parts by weight of n-butyl |
| | | acetate (NBAC) and 40 parts by weight of propylene glycol |
| | | monomethyl ether (PGME) |
| | A-3 | A mixed solvent formed by mixing 70 parts by weight of propylene |
| | | glycol monomethyl ether (PGME) and 30 parts by weight of |
| | | propylene glycol monomethyl ether acetate (PGMEA) |
| Fluorine-Containing | B-1 | A compound represented by the |
| Additive (B) | | following Formula (B-1-1) |
| | | 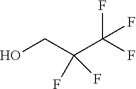 |
| | | Formula (B-1-1) |
| | B-2 | A polymer represented by Formula (B-2), in which: |
| | | 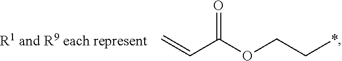 |
| | | R², R⁴, R⁶, and R⁸ each represent hydrogen, R⁵ represents a methyl group, |
| | | 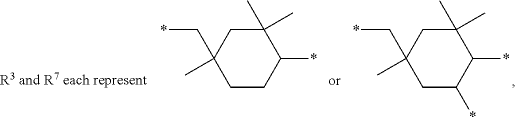 [SMILES: *CC1(C)CCC(*)C(C)(C)C1 ; *CC1(C)CC(*)C(*)C(C)(C)C1] |
| | | X⁸ represents *—CH₂CF₃, and |
| | | *represents a bonding position |
| | B-3 | A polymer represented by Formula (B-3), in which: |
| | | X⁹ and X¹⁰ each represent CᵣF₂ᵣ₋₁ (r = 8 to 11), |
| | | R¹⁰ to R¹³ each represent hydrogen, |
| | | T represents hydrogen, |
| | | j and q each represent an integer of 2 to 18, |
| | | k represents an integer of 2 to 13, |
| | | p represents an integer of 2 to 3 |
| | | The molecular weight is 2000 to 5000. |
| | B-4 | A compound represented by the following Formula (B-4), in which |
| | | the sum of x and y is approximately 6 |
| | | 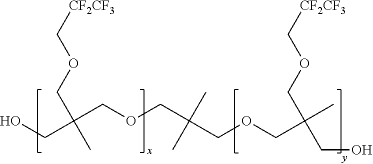 |
| | | Formula (B-4) |

TABLE 2

| Constituent | | Embodiment | | | | | | |
|---|---|---|---|---|---|---|---|---|
| (Unit: part by weight) | | 1 | 2 | 3 | 4 | 5 | 6 | 7 |
| Solvent (A) | A-1 | 99.4 | — | 99.4 | — | — | — | — |
| | A-2 | — | 99.4 | — | — | — | — | — |
| | A-3 | — | — | — | 99.9 | 99.8 | 99.7 | 99.6 |
| Fluorine- | B-1 | 0.6 | — | — | — | — | — | — |
| Containing | B-2 | — | 0.6 | — | — | — | — | — |
| Additive (B) | B-3 | — | — | 0.6 | 0.1 | 0.2 | 0.3 | 0.4 |
| | B-4 | — | — | — | — | — | — | — |
| Evaluation | Protrusion | ◯ | ◯ | ⊚ | ⊚ | ⊚ | ⊚ | ⊚ |
| Result | Removability | | | | | | | |

| Constituent | | Embodiment | | | | Comparative Example | | |
|---|---|---|---|---|---|---|---|---|
| (Unit: part by weight)) | | 8 | 9 | 10 | 11 | 1 | 2 | 3 |
| Solvent (A) | A-1 | — | — | — | — | 95 | 99.4 | — |
| | A-2 | — | — | — | — | — | — | — |
| | A-3 | 99.6 | 99.6 | 99.6 | 99.7 | — | — | 99.4 |
| Fluorine- | B-1 | 0.2 | 0.2 | — | 0.1 | 5 | — | — |
| Containing | B-2 | — | 0.2 | 0.2 | 0.1 | — | — | — |
| Additive (B) | B-3 | 0.2 | — | 0.2 | 0.1 | — | — | — |
| | B-4 | — | — | — | — | — | 0.6 | 0.6 |
| Evaluation | Protrusion | ⊚ | ◯ | ⊚ | ⊚ | Δ | Δ | Δ |
| Result | Removability | | | | | | | |

### Evaluation Method

### Protrusion Removability

The prepared thinner composition is sprayed through the nozzle of the coating equipment (model MK8, manufactured by Tokyo Electron Limited) onto the edge of the surface of the substrate (such as a semiconductor wafer) on which the photoresist composition has been coated. Next, baking is performed at 220° C. for 60 seconds, and then the photoresist is obtained. Afterward, the wafer surface is scanned with the tip probe of a film thickness profilometer (α-step) (model 138370, manufactured by Veeco). As the trajectory of the probe scanning across the wafer surface, a sensor is used to record changes in the vertical movement of the probe. The signal generated by the changes in the vertical movement of the probe can display the one-dimensional profile of the wafer surface. Through the profile, the undulating morphology and evenness of the wafer surface after being coated with the photoresist may be known, thereby measuring the height of the photoresist protrusions on the edge of the wafer. Compared with the height of the protrusions on the edge of the substrate surface sprayed with conventional wafer processing liquid, the more the height of the protrusions on the edge of the substrate surface sprayed with the thinner composition prepared by the Embodiment/Comparative Example is reduced, the more it shows that the thinner composition has a good protrusion removability. The evaluation criteria for protrusion removability are as follows:
⊚: 95%≤height reduction ratio of the protrusions on the edge of the substrate surface;
○: 75%≤height reduction ratio of the protrusions on the edge of the substrate surface <95%;
Δ: 50%≤height reduction ratio of the protrusions on the edge of the substrate surface <75%;
x: height reduction ratio of the protrusions on the edge of the substrate surface <50%.

### Evaluation Result

As can be seen from Table 2, the embodiment in which the thinner composition includes the fluorine-containing additive (B) having a specific structure has a good protrusion removability when used in the method for substrate processing, and can be applied to manufacturing processes of semiconductor devices, display devices, or optical elements. On the other hand, the comparative example in which the thinner composition does not include the fluorine-containing additive (B) having a specific structure shows a poor protrusion removability when used in the method for substrate processing.

In addition, based on 100 parts by weight of the thinner composition, compared with a thinner composition (Comparative Example 1) in which the amount of the fluorine-containing additive (B) is not in the range of 0.001 parts by weight to 3 parts by weight, the thinner composition (Embodiments 1 to 11) in which the amount of the fluorine-containing additive (B) is 0.001 parts by weight to 3 parts by weight has a better protrusion removability when used in the method for substrate processing.

In addition, compared with the thinner composition (Embodiments 1 to 2 and 9) in which the fluorine-containing additive (B) does not include a polymer represented by Formula (B-3), the thinner composition (Embodiments 3 to 8 and 10 to 11) in which the fluorine-containing additive

(B) includes a polymer represented by Formula (B-3) has a better protrusion removability when used in the method for substrate processing.

In summary, when the thinner composition of the disclosure includes the fluorine-containing additive (B) having the specific structure, the thinner composition has a good protrusion removability when used in the method for substrate processing, and can be applied to manufacturing processes of semiconductor devices, display devices, or optical elements, thereby improving the performance of the formed devices or elements.

Although the disclosure has been disclosed above through the embodiments, the embodiments are not intended to limit the disclosure. Persons with ordinary knowledge in the relevant technical field can make some changes and modifications without departing from the spirit and scope of the disclosure. Therefore, the protection scope of the disclosure shall be determined by the appended claims.

What is claimed is:

1. A thinner composition, comprising:
a solvent (A); and a fluorine-containing additive (B), wherein the fluorine-containing additive (B) comprises a compound represented by the following Formula (B-1), a polymer represented by the following Formula (B-2), a polymer represented by the following Formula (B-3), or a combination thereof, 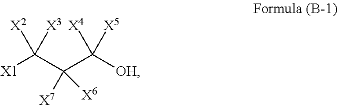
in Formula (B-1), X¹ to X⁷ each represent hydrogen, fluorine, or a fluorine-containing alkyl group having 1 to 2 carbon atoms, and at least one of X¹ to X⁷ is fluorine or a fluorine-containing alkyl group having 1 to 2 carbon atoms; 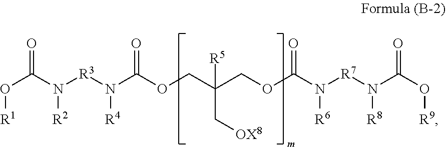
in Formula (B-2), R¹ and R⁹ each represent C_{y}H_{2y-3}O_{z}, wherein y represents an integer of 4 to 25, and z represents an integer of 1 to 7,
R², R⁴, R⁵, R^{6,} and R⁸ each represent hydrogen, an alkyl group having 1 to 5 carbon atoms, or an alkoxy group having 1 to 5 carbon atoms,
R³ and R⁷ each represent CₙH₂ₙ₋₂, wherein n represents an integer of 4 to 25,
X⁸ represents a fluorine-containing alkyl group having 1 to 3 carbon atoms,
m represents an integer of 2 to 39,
in response to m being an integer greater than or equal to 3, the plurality of R⁵s are the same as or different from each other, and the plurality of X⁸s are the same as or different from each other; 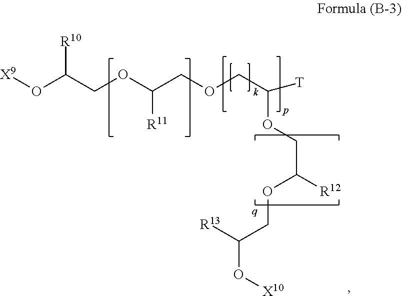
in Formula (B-3), X⁹ and X¹⁰ each represent CᵣF₂ᵣ₋₁, wherein r represents an integer of 2 to 15,
R¹⁰ to R¹³ each represent hydrogen, an alkyl group having 1 to 3 carbon atoms, an alkoxy group having 1 to 3 carbon atoms, or a hydroxyl group,
T represents hydrogen, an alkyl group having 1 to 3 carbon atoms, an alkoxy group having 1 to 3 carbon atoms, a hydroxyl group, a carboxyl group, *—COOCH₃, *—COOC₂H₅, an aldehyde group, an amine group, *—OSO₃H, *—OSO₃NH₄, *—OSO₃Na, *—OSO₃K, wherein * represents a bonding position,
j and q each represent an integer of 2 to 30,
k represents an integer of 0 to 20,
p represents an integer of 1 to 9,
in response to j, k, p, and q each being an integer greater than or equal to 2, the plurality of R¹¹s are the same as or different from each other, the plurality of R¹²s are the same as or different from each other, the plurality of R¹³s are the same as or different from each other, and the plurality of X¹⁰s are the same as or different from each other.

2. The thinner composition as claimed in claim 1, wherein the solvent (A) comprises propylene glycol monomethyl ether, propylene glycol monomethyl ether acetate, n-butyl acetate, N-methylpyrrolidone, isobutanol, 4-methyl-2-pentanol, γ-butyrolactone, cyclohexanone, cyclohexanol, dimethyl sulfoxide, ethanol, methanol, butanol, or a combination thereof.

3. The thinner composition as claimed in claim 1, wherein the solvent (A) is a mixed solvent, and the mixed solvent is formed by mixing at least two different organic solvents.

4. The thinner composition as claimed in claim 3, wherein a boiling point of the mixed solvent is 70° C. to 170° C., and a turbidity is less than or equal to 0.02 NTU.

5. The thinner composition as claimed in claim 1, wherein the solvent (A) comprises propylene glycol monomethyl ether, and further comprises at least one of propylene glycol monomethyl ether acetate, n-butyl acetate, N-methylpyrrolidone, isobutanol4-methyl-2-pentanol, γ-butyrolactone, cyclohexanone, cyclohexanol, dimethyl sulfoxide, ethanol, methanol, and butanol.

6. The thinner composition as claimed in claim 1, wherein the solvent (A) is a mixed solvent formed by mixing propylene glycol monomethyl ether and n-butyl acetate, and a mixing ratio of propylene glycol monomethyl ether and n-butyl acetate is 5:95 to 45:55.

7. The thinner composition as claimed in claim 1, wherein the solvent (A) is a mixed solvent formed by mixing propylene glycol monomethyl ether and propylene glycol monomethyl ether acetate, and a mixing ratio of propylene glycol monomethyl ether and propylene glycol monomethyl ether acetate is 50:50 to 90:10.

8. The thinner composition as claimed in claim 1, wherein based on 100 parts by weight of the thinner composition, an amount of the fluorine-containing additive (B) is 0.001 parts by weight to 3 parts by weight.

9. A method for substrate processing, comprising:
applying the thinner composition as claimed in claim 1 to a surface of the substrate.

10. The method for substrate processing as claimed in claim 9, wherein the thinner composition is applied to an edge of the surface of the substrate.

11. The method for substrate processing as claimed in claim 9, wherein a photoresist composition has been coated on the surface of the substrate, and the thinner composition removes protrusions on an edge of a surface of the photoresist composition.
